(19) United States
(12) Patent Application Publication
(10) Pub. No.: US 2014/0103522 A1
(43) Pub. Date: Apr. 17, 2014

(54) SEMICONDUCTOR SUBSTRATE, SEMICONDUCTOR DEVICE, AND METHOD OF MANFACTURING SEMICONDUCTOR SUBSTRATE

(71) Applicant: OLYMPUS CORPORATION, Tokyo (JP)

(72) Inventor: Yoshiaki Takemoto, Tokyo (JP)

(73) Assignee: OLYMPUS CORPORATION, Tokyo (JP)

(21) Appl. No.: 14/035,516

(22) Filed: Sep. 24, 2013

(30) Foreign Application Priority Data
Oct. 15, 2012 (JP) 2012-228294

(51) Int. Cl. H01L 23/00

(52) U.S. Cl. CPC H01L 24/13; H01L 24/11
USPC 257/737; 438/613

(57) ABSTRACT

A semiconductor substrate having a base material and a connection portion provided on at least one surface of the base material. The connection portion includes: a non-conductive wall portion so as to surround a concave portion formed on the base material; an electrode portion disposed on a bottom surface of a concave portion; and a metal portion disposed in contact with the electrode portion.

### BACKGROUND OF THE INVENTION

1. Field of the Invention

The present invention relates to a semiconductor substrate, a semiconductor device using the semiconductor substrate, and a method of manufacturing the semiconductor substrate.

Priority is claimed on Japanese Patent Application No. 2012-228294 filed on Oct. 15, 2012, the entire content of which is incorporated herein by reference.

2. Description of Related Art

In order to achieve miniaturization and high functionality of a system, a semiconductor device having a smaller size and higher performance is required, and bonding wafers on which a number of minute bumps are formed is being investigated. Further, with the progress of bump miniaturization, it is becoming more necessary to perform alignment (position adjustment) between substrates with high accuracy when bonding the substrates to each other.

In order to electrically connect electrodes of a wafer on which a number of minute bumps are formed, it is necessary to apply a load to the wafer as a base material. However, the load required at this time increases with the number of electrodes. For example, when electrodes having a diameter of about 10 μm are formed on the entire surface of a wafer of 8 inches (20.32 cm), the number of electrodes is several hundred million, and the load required for bonding amounts to several tons. Further, in order to realize the bonding of the substrates in a large area of a wafer or the like, a load during bonding should be increased to suppress warpage of the substrate or the like. On the other hand, in order to prevent damage to the electrode and the wafer, it is desirable to prevent such a load from being concentrated on a specific electrode.

Generally, when wafers (or semiconductor chips) are bonded to each other, bonding is performed using solder as a bump. Since miniaturization of the bump is required to meet the request of miniaturization and higher performance of semiconductor devices, if the solder is used as the bump, the bump may cause a connection failure result from a solder bridge or the like, by crushing of the bump and migration of solder components.

Japanese Unexamined Patent Application, First Publication No. 2004-63770 proposes the following method. In the method, electrodes are formed on the surface of one substrate, and a resin film is formed to cover the formed electrodes. After that, openings are formed so that electrode portions are exposed in a part of the formed resin film, and metal balls (bumps) are supplied to the openings. Thereafter, another substrate is laminated thereon, and then heating treatment is performed under pressure.

Further, Japanese Unexamined Patent Application, First Publication No. 2005-32885 proposes a method of bonding substrates in a state in which the solder bumps are not melted and melting the solder after the bonding.

### SUMMARY OF THE INVENTION

According to a first aspect of the present invention, a semiconductor substrate includes a base material and a connection portion provided on at least one surface of the base material. The connection portion includes: an electrode portion disposed on a bottom surface of a concave portion formed on the base material; a non-conductive wall portion disposed outside of the concave portion so as to surround the concave portion; and a metal portion disposed in contact with the electrode portion.

According to a second aspect of the present invention, in the first aspect, a volume of a sphere whose diameter is equal to a diameter of the electrode portion may be smaller than a volume surrounded by the wall portion.

According to a third aspect of the present invention, in the first aspect, a plurality of the connection portions are provided, and the plurality of connection portions may be different in sizes.

According to a fourth aspect of the present invention, in the third aspect, the one surface of the base material may be divided into predetermined unit regions, and the connection portions disposed at an outermost periphery of the predetermined unit regions may be larger than the other connection portions.

According to a fifth aspect of the present invention, in a semiconductor device in which a plurality of semiconductor substrates are laminated thereon and electrically connected to each other, at least one of the plurality of semiconductor substrates is the semiconductor substrate according to the first aspect.

According to a sixth aspect of the present invention, a method of manufacturing a semiconductor substrate having a base material and a connection portion disposed on one surface of the base material includes the steps of: forming a concave portion on one surface of the base material; forming an electrode portion on a bottom surface of the concave portion; forming a wall portion so as to surround the concave portion at an outside of the concave portion; and disposing a metal portion so as to contact with the electrode portion.

### BRIEF DESCRIPTION OF THE DRAWINGS

FIG. 1 is a plan view illustrating a substrate according to a first embodiment of the present invention.

FIG. 2 is an enlarged view illustrating a unit region of the substrate according to the first embodiment of the present invention.

FIGS. 3A and 3B are views illustrating a connection portion of the substrate according to the first embodiment of the present invention.

FIGS. 4A to 4G are views illustrating a method of manufacturing the substrate according to the first embodiment of the present invention.

FIG. 5 is a view illustrating the connection portion of the substrate according to the first embodiment of the present invention.

FIG. 6 is a view illustrating connection portions of a substrate according to a second embodiment of the present invention.

FIG. 7 is an enlarged view illustrating a unit region of a substrate according to a third embodiment of the present invention.

FIG. 8 is an enlarged view illustrating the unit region of the substrate according to the third embodiment of the present invention.

FIG. 9 is a view illustrating a semiconductor device according to the third embodiment of the present invention.

FIGS. 10A to 10C are views illustrating a method of manufacturing the semiconductor device according to the third embodiment of the present invention.

### DETAILED DESCRIPTION OF THE INVENTION

### First Embodiment

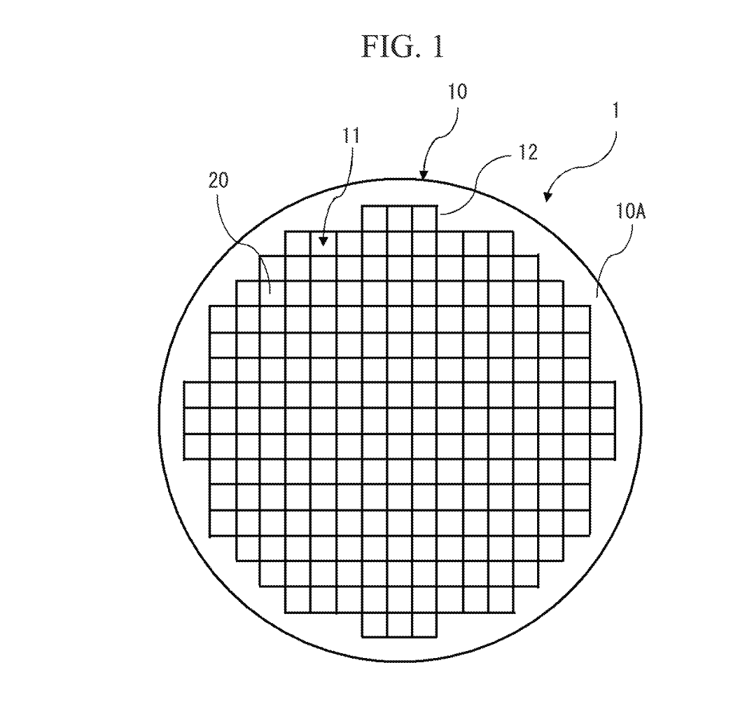

A first embodiment according to the present invention will be described with reference to FIGS. 1 to 4G

FIG. 1 is a plan view illustrating a substrate 1 according to the present embodiment. The substrate 1 includes a base material 10 having a plate shape or sheet shape and connection portions 20. The plurality of connection portions 20 are formed on a surface of the base material 10.

The base material 10 is formed of an insulator or a semiconductor to a predetermined thickness in a plate or sheet shape. Examples of the insulator and semiconductor which constitute the base material 10 may include silicon, a resin, a ceramic, glass and the like. In the present embodiment, as the base material 10, a silicon wafer is used.

Further, although not shown in the drawings, wirings electrically connected to the connection portions 20 are formed in the base material 10. The wirings may be formed on one surface or both surfaces of the base material 10 by printing, etching or the like, may be formed to pass through the base material like a via or the like, or may be three-dimensional wirings formed using a laminating technique. Further, these may be combined appropriately.

One surface of the base material 10 is a bonding surface 10A that is bonded to another substrate. A plurality of rectangular unit regions 11 are provided on the bonding surface 10A. The connection portions 20 are formed in the same layout on the unit regions 11, and the same type of wirings are formed thereon.

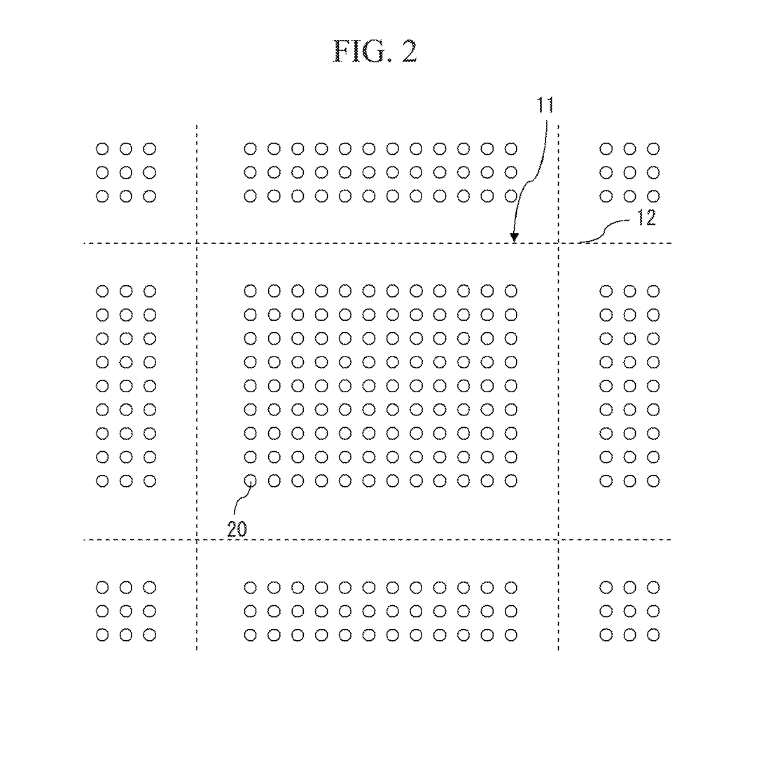

FIG. 2 is a schematic enlarged view illustrating the unit region 11. The connection portions 20 are disposed in a two-dimensional arrangement on the base material 10. A boundary 12 between adjacent unit regions serves as a cutting line when segmenting, and is known as a scribe line. However, the boundary 12 is an imaginary line, and is not necessarily formed with a line shape on the base material 10.

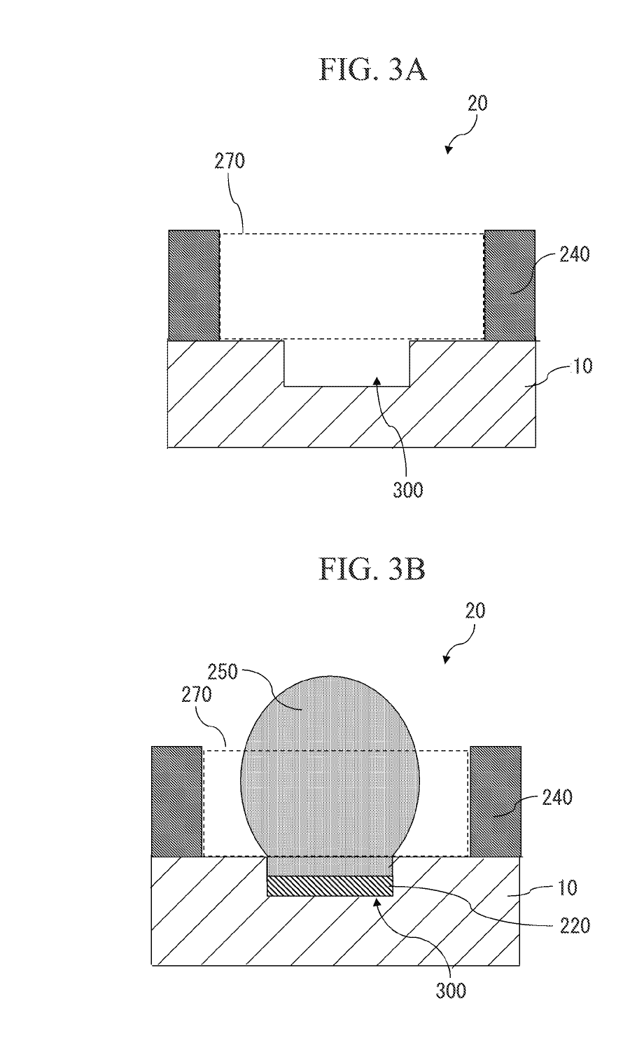

FIGS. 3A and 3B are cross-sectional views in a thickness direction of the substrate 1 schematically illustrating the connection portion 20. FIG. 3A is a cross-sectional view in the thickness direction of the substrate 1 of the connection portion 20 in which an electrode 220 and a metal portion 250 are not illustrated. FIG. 3B is a cross-sectional view in the thickness direction of the substrate 1 of the connection portion 20 in which the electrode 220 and the metal portion 250 are illustrated. The connection portion 20 includes the electrode 220, a resin portion (wall portion) 240, the metal portion 250 and a concave portion 300.

The electrode 220 is formed on a bottom surface of the concave portion 300 formed on one surface in the thickness direction of the base material 10. The electrode 220 is formed of any one of Cu, Ni, Ta, TaN, Ti, and TiN, an alloy thereof, or a multi-layer structure thereof. The electrode 220 electrically connects between a wiring layer (not shown) provided inside the base material 10 and the metal portion 250. Further, in the present embodiment, the shape in a plan view of the electrode 220 may be circular, polygonal or the like.

The resin portion 240 is provided for preventing a connection failure such as a bridge from occurring when connecting the metal portion 250 to the other substrate. The resin portion 240 is formed of an insulator such as a resin material, and is provided to surround the electrode 220. Further, the resin material may be a material containing a flux composition. Further, a metal layer 290 or the like which will be described later is formed in an opening 270 which is an area surrounded by the resin portion 240.

The metal portion 250 is disposed on top of the electrode 220 to be in contact with the electrode 220 and is electrically connected to the wiring via the electrode 220. Further, the metal portion 250 is, for example, formed with a bump or the like obtained by melting a metallic material such as solder.

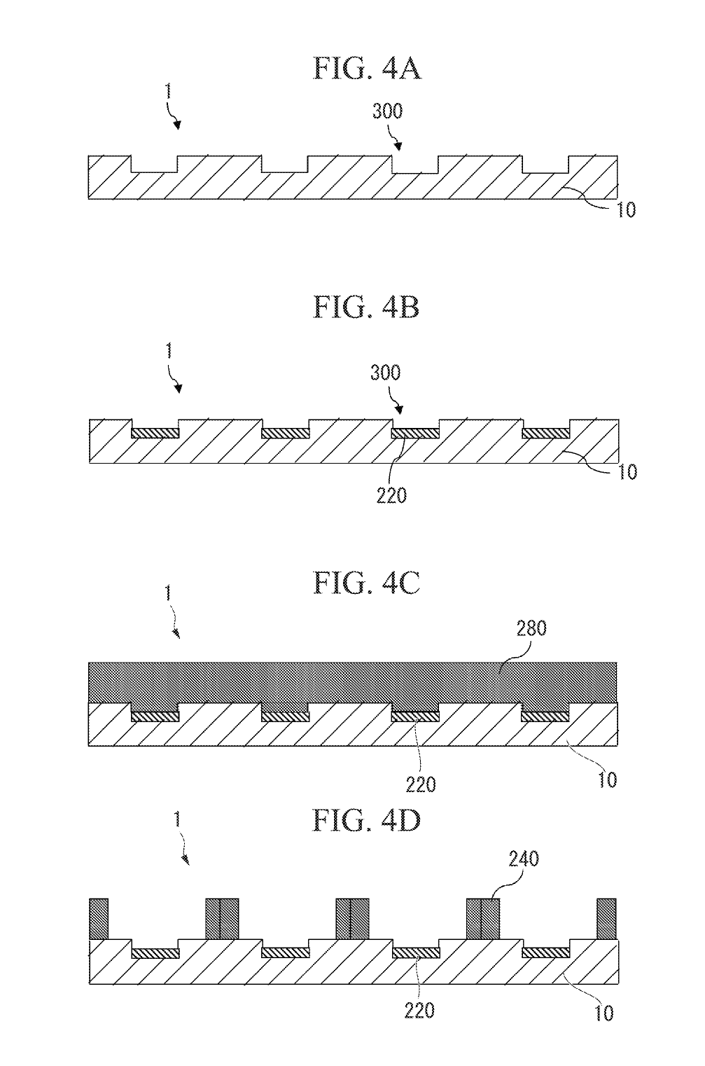

FIGS. 4A to 4G are views illustrating a method of manufacturing the substrate 1 according to the present embodiment.

As illustrated in FIG. 4A, in the substrate 1, the concave portion 300 formed to a predetermined depth on one surface in the thickness direction of the base material 10 by etching or the like.

Next, as illustrated in FIG. 4B, in the substrate 1, the electrode 220 is formed on the bottom surface of the concave portion 300. Here, the electrode 220 is formed by a sputtering method or a plating method, but preferably is formed using an electroless plating method.

Next, as illustrated in FIG. 4C, in the substrate 1, a resin is coated on the surface on which the electrode 220 is formed to form a resin film 280. Here, the resin is coated by spin coating or the like.

Next, as illustrated in FIG. 4D, in the substrate 1, a part of the resin film 280 is removed by etching or the like so that the electrode 220 is exposed. By this process, the resin portion (wall portion) 240 formed so as to surround the electrode 220 is formed.

Next, as illustrated in FIG. 4E, in the substrate 1, a metal is supplied on the entire surface of the base material 10 on which the electrode 220 is formed to form a metal layer 290. Here, the metal is a material such as solder or the like and is supplied by a printing method, a sputtering method, a plating method or the like.

Next, as illustrated in FIG. 4F, in the substrate 1, an excess metal which is a part of the coated metal layer 290 and exceeds a height of the resin portion 240 is removed by using a cutting tool 260. Further, although an example of using the cutting tool 260 has been described in the present embodiment, the excess metal may be removed using Chemical Mechanical Polishing (CMP) or a squeegee.

Next, the metal layer 290 is melted to form an ellipsoidal metal portion 250 as illustrated in FIG. 4G by heating the substrate 1 at a temperature equal to or greater than a melting temperature of the supplied metal layer 290.

Here, the base material 10 has low wettability with respect to the metal layer 290 since the base material 10 is formed of the insulator or the semiconductor. Therefore, as illustrated with an arrow 5 in FIG. 4G, a force 5 works against the metal portion 250 from a sidewall of the concave portion 300. Similarly, as illustrated with an arrow 6 in FIG. 4G, a force 6 works against the metal portion 250 from the surface of the base material 10. Due to the forces 5 and 6, even though heating is performed under pressure when the substrates are bonded, the metal portion 250 becomes hard to crush. Therefore, the substrates can be electrically connected even without pressing the substrates until the resin portion 240 is deformed. As a result, high precision alignment between the substrates can be achieved through self-alignment. Further, when the substrates are bonded, even though the metal portion 250 is melted by the heating treatment of the substrate, a connection failure due to the bridge or the like can be prevented by the resin portion 240.

Further, in the present embodiment, when the shape in a plan view of the electrode 220 is circular, the volume of the metal portion 250 which is shaped like a sphere with a diameter corresponding to the diameter of the electrode 220 may be set to be smaller than the volume of the opening 270. In this case, when the substrates are bonded, even though the pressure for pressing the substrates increases, it is possible to increase the effect of preventing a connection failure due to the bridge or the like. Further, when the shape in plan view of the electrode 220 is polygonal, the volume of the metal portion (a sphere) with a diameter corresponding to a length of a diagonal of the electrode 220 may be set to be smaller than the volume of the opening 270.

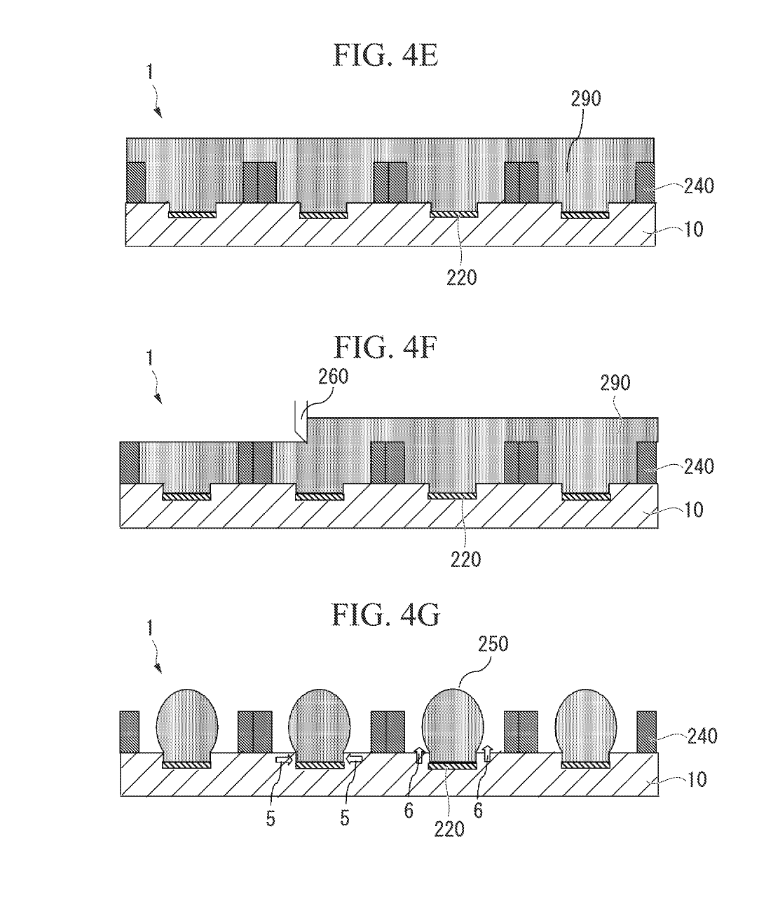

Further, although the electrode 220 is formed on the bottom surface of the concave portion 300 in the present embodiment, all of the inside of the concave portion 300 may be filled with the electrode 220, as illustrated in FIG. 5. In this case, the force indicated by the arrow 5 in FIG. 4G does not work against the metal section 250, but the force 6 (arrow 6) works. By this force 6, even though the substrates are heated under pressure while being bonded, the metal portion 250 becomes similarly hard to crush. Therefore, since the substrates can be electrically connected even without pressing the substrates until the resin portion 240 is deformed, high precision alignment between the substrates can be achieved through self-alignment.

### Second Embodiment

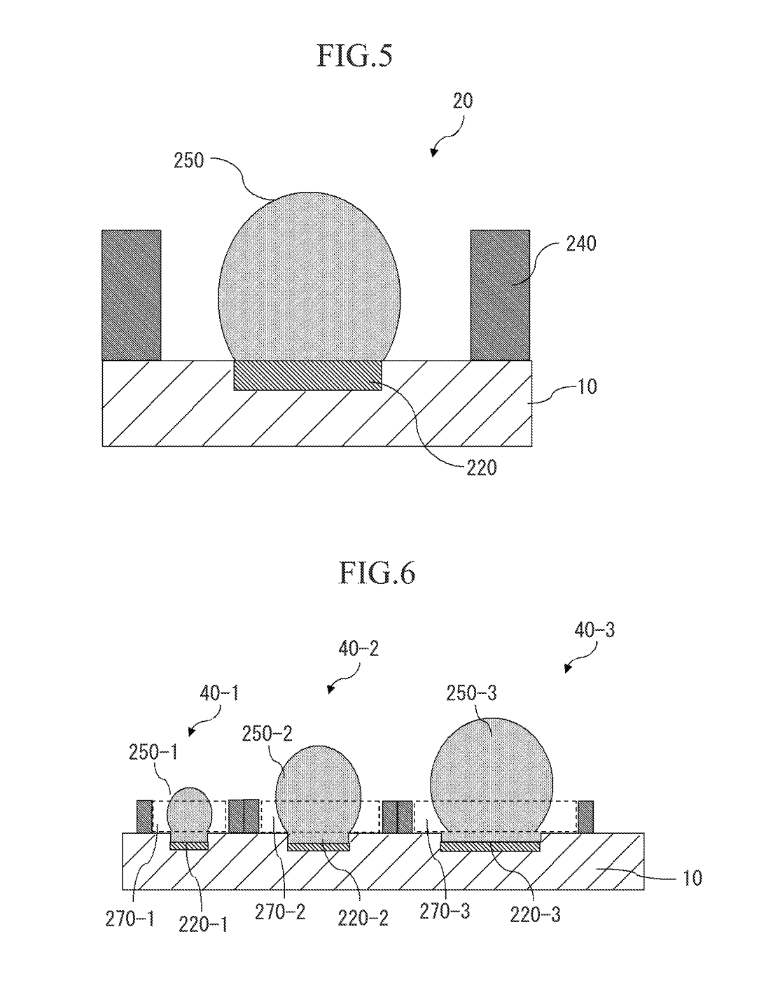

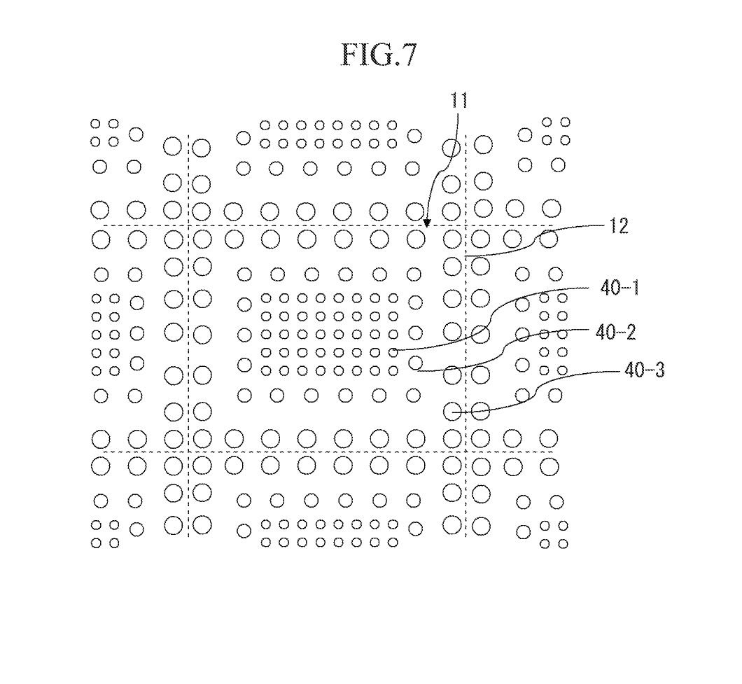

Next, a substrate of a second embodiment will be described using FIGS. 6 and 7.

Further, the substrate according to the second embodiment is different from the substrate according to the first embodiment only in connection portions. Therefore, the description of the portions other than the connection portions will be omitted.

FIG. 6 is a view illustrating connection portions 40-1, 40-2 and 40-3 of the present embodiment and a cross-sectional view of the substrate.

In the substrate of the present embodiment, the sizes of the connection portions 40-1, 40-2 and 40-3 are all different. The sizes increase in the order of the connection portion 40-1, the connection portion 40-2, and the connection portion 40-3.

The sizes of the connection portions 40-1, 40-2 and 40-3 are formed depending on the volumes of openings 270-1, 270-2 and 270-3. The connection portions 40-1, 40-2 and 40-3 having different sizes are formed to different sizes by varying the volumes of the openings 270-1, 270-2 and 270-3. Here, in order to form the openings 270-1, 270-2 and 270-3 having different volumes, the heights of all of the openings 270-1, 270-2 and 270-3 are the same (also the same as heights of resin portions 240-1, 240-2 and 240-3) and the opening areas are varied. Here, opening areas are cross-sectional areas of the openings 270-1, 270-2 and 270-3 in a direction perpendicular to the thickness of the substrate 1.

Electrodes 220-1, 220-2 and 220-3 are formed in the plan view shape to have a circular shape as in the first embodiment, but electrodes may be polygonal or the like.

Further, the ratio of the surface area in the electrode 220-1 to the opening area of the opening 270-1, the ratio of the surface area in the electrode 220-2 to the opening area of the opening 270-2, and the ratio of the surface area in the electrode 220-3 to the opening area of the opening 270-3 are preferably equal, but are not limited thereto.

FIG. 7 is a view shown from the surface 10A of the substrate 1 in the present embodiment to which the other substrate is bonded.

The connection portions 40-1 are disposed near a central portion of a unit region 11. The connection portions 40-3 are disposed at the outermost periphery of the unit region 11. The connection portions 40-2 are disposed between the connection portions 40-1 and the connection portions 40-3. That is, the connection portions 40-1, 40-2 and 40-3 are provided such that the sizes of the connection portions increase as the connection portions approach a boundary 12 from the central portion of the unit region 11.

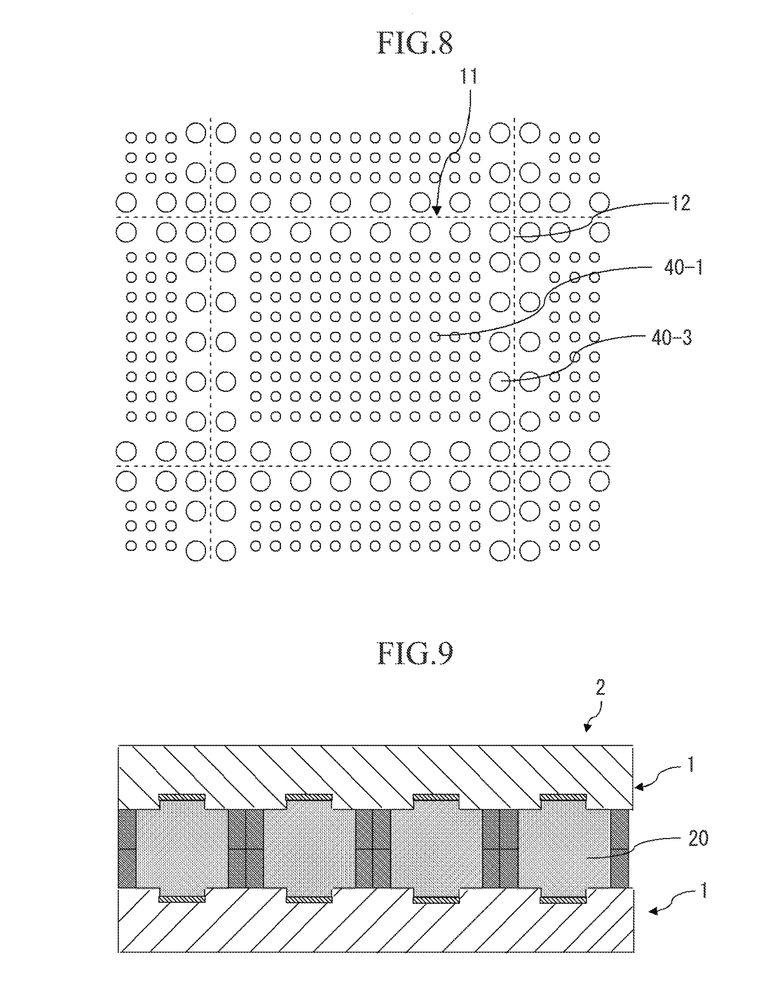

Thus, since the sizes of the connection portions increase as the connection portions approach the boundary 12, when bonding between the substrates is performed, the substrates can exhibit the self-alignment effect in a wider range. As a result, it is possible to achieve more precise alignment and it is also possible to prevent a connection failure due to a bump being crushed, even when the weighted load increases while bonding between the substrates is performed. Further, although an example in which the sizes of the connection portions 40-1, 40-2 and 40-3 are all different has been described in the present embodiment, the size of at least one of the connection portions may be different. For example, as illustrated in FIG. 8, only the connection portions disposed at the outermost periphery of the unit region 11 may be configured to be larger than the other connection portions.

### Third Embodiment

Next, a semiconductor device in which a plurality of the substrate 1 described the first embodiment or the second embodiment is provided will be described. Further, this embodiment will be described using a semiconductor device in which a plurality of the substrates 1 described the first embodiment are provided.

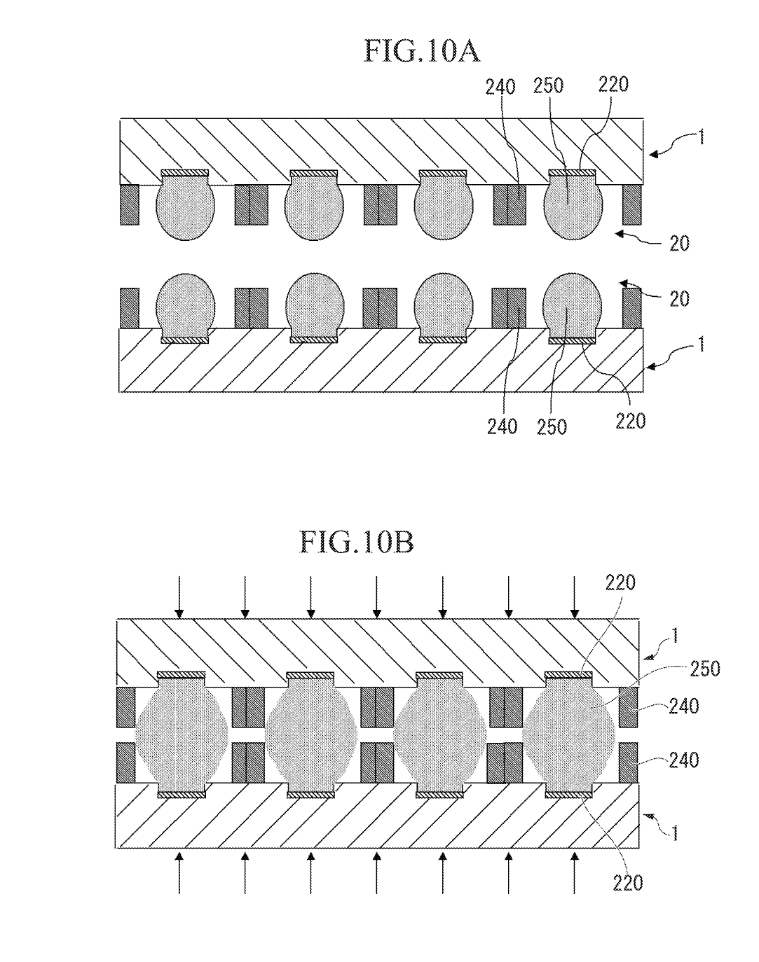

FIG. 9 is a view illustrating a semiconductor device 2 of the present embodiment.

The semiconductor device 2 is a device in which two substrates are laminated and electrically connected via connection portions of each of the substrates. Although an example using two substrates of the first embodiment is described in the present embodiment, two substrates of the second embodiment may be used, or the substrate of the first embodiment may be used as one substrate and the substrate of the second embodiment may be used as the other substrate. Further, the substrate of the first embodiment or the substrate of the second embodiment may be used as one substrate and a substrate other than those of the present invention may be used as the other substrate. That is, the substrate of the first embodiment or the substrate of the second embodiment may be used as the substrate of at least one side.

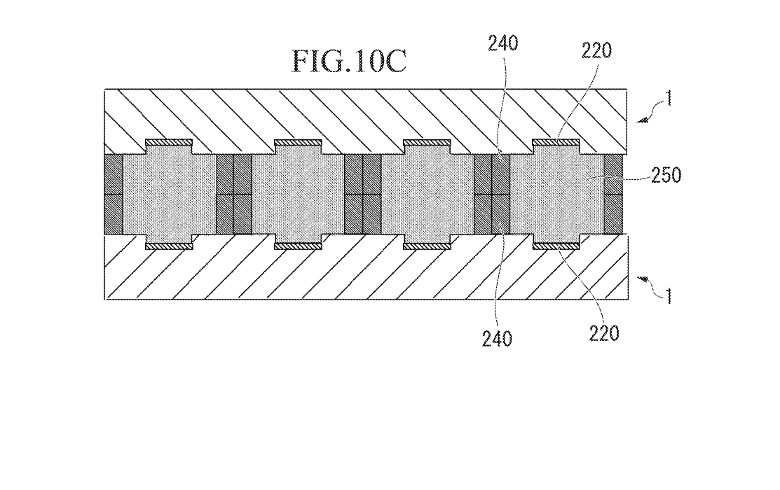

FIGS. 10A and 10B are views illustrating a method of manufacturing the semiconductor device 2 according to the present embodiment.

First, as illustrated in FIG. 10A, in order for the metal portions 250 to come close to one another, the substrates 1 are moved close to each other while performing alignment (positioning) therebetween.

Next, the substrates 1 are pressed under pressure and simultaneously heated to a melting temperature of the metal portions 250, and connections are thereby achieved between the metal portions 250 as illustrated in FIG. 10B. At this time, the metal portions 250 are hard to crush even when the substrates are pressed with the pressure described in the first embodiment, and therefore, even though the substrates are not pressed until the resin portions 240 are deformed, the metal portions 250 are possible to be connected to each other. Thus, it is possible to perform the alignment of the substrates with high precision due to the force working by the self-alignment. Further, even though the force increases when bonding the substrates, due to the resin portions 240, it is possible to prevent a connection failure due to a bump being crushed.

Next, the pressing and heating processes with respect to the substrates end, and thus the semiconductor device 2 illustrated in FIG. 10C is completed. Further, the processes shown in FIGS. 10A to 10C are performed in a predetermined atmosphere such as in a vacuum, a nitrogen atmosphere or a formic acid atmosphere.

While preferred embodiments of the invention have been described and illustrated above, it should be understood that these are exemplary embodiments of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor substrate comprising a base material and a connection portion provided on at least one surface of the base material,
wherein the connection portion includes:
an electrode portion disposed on a bottom surface of a concave portion formed on the base material;
a non-conductive wall portion disposed outside of the concave portion so as to surround the concave portion; and
a metal portion disposed in contact with the electrode portion.

2. The semiconductor substrate according to claim 1,
wherein a volume of a sphere whose diameter is equal to a diameter of the electrode portion is smaller than a volume which is surrounded by the wall portion.

3. The semiconductor substrate according to claim 1,
wherein a plurality of the connection portions are provided, and
the plurality of connection portions are indifferent sizes.

4. The semiconductor substrate according to claim 3,
wherein the one surface of the base material is divided into predetermined unit regions, and the connection portions disposed at an outermost periphery of the predetermined unit regions are larger than the other connection portions.

5. A semiconductor device in which a plurality of semiconductor substrates are laminated and electrically connected to each other,
wherein at least one of the plurality of semiconductor substrates is the semiconductor substrate according to claim 1.

6. A method of manufacturing a semiconductor substrate having a base material and a connection portion disposed on one surface of the base material, the method comprising the steps of:
forming a concave portion in one surface of the base material;
forming an electrode portion on a bottom surface of the concave portion;
forming a wall portion so as to surround the concave portion at an outside of the concave portion; and
disposing a metal portion so as to contact with the electrode portion.
